(19) United States
(12) Patent Application Publication
(10) Pub. No.: US 2025/0206526 A1
(43) Pub. Date: Jun. 26, 2025

(54) ARTICLE CONVEYANCE DEVICE

(71) Applicant: DAIFUKU CO., LTD., Osaka (JP)

(72) Inventors: Daichi TOMIDA, Shiga (JP); Daisuke OGAWA, Shiga (JP); Yoshitaka DEGUCHI, Shiga (JP)

(73) Assignee: DAIFUKU CO., LTD., Osaka (JP)

(21) Appl. No.: 18/927,051

(22) Filed: Oct. 25, 2024

(30) Foreign Application Priority Data
Dec. 20, 2023 (JP) 2023-214765

(51) Int. Cl. B65G 1/04; B61G 11/16

(52) U.S. Cl. CPC B65G 1/0457; B61G 11/16

(57) ABSTRACT

An article conveyance device includes a travelling section configured to travel along a travelling path, a body section suspended from the travelling section, and a power storage section storing electricity. The body section includes a first structure extending downward from a travelling section side. The first structure accommodates the power storage section and includes an impact absorption member arranged in a forward position on a side farther from a center position of the body section in a front-and-rear direction than the power storage section.

This Nonprovisional application claims priority under 35 U.S.C. § 119 on Patent Application No. 2023-214765 filed in Japan on Dec. 20, 2023, the entire contents of which are hereby incorporated by reference.

### TECHNICAL FIELD

The present disclosure relates to an article conveyance device.

### BACKGROUND ART

Recently, automatic conveyance of articles using article conveyance devices has been put into practical use in factories, warehouses, and the like. As such an article conveyance device, for example, a ceiling carrier travelling along a rail installed on the ceiling is disclosed in Patent Literature 1. The ceiling carrier disclosed in Patent Literature 1 is provided with a cover, for covering a conveyance device thereof for conveying an article, which is provided in a front-and-rear direction of the conveyance device.

### CITATION LIST

### Patent Literature

### [Patent Literature 1]

Japanese Patent Application Publication Tokukai No. 2017-088394

### SUMMARY OF INVENTION

### Technical Problem

Some article conveyance devices include power storage sections for storing electricity. The ceiling carrier disclosed in Patent Literature 1 has a problem in that the power storage section may be damaged, for example, in a collision with an obstacle or the like.

It is an object of the present disclosure to provide an article conveyance device that makes it possible to prevent a power storage section from being damaged.

### Solution to Problem

In order to solve the foregoing problem, an article conveyance device of the present disclosure includes: a travelling section configured to travel along a travelling path; a body section suspended from the travelling section; and a power storage section configured to store electricity. The body section includes a structure arranged at at least one of a front part or a rear part of the body section in a case where direction a travelling of the travelling section corresponds to a front-and-rear direction, the structure extending downward from a travelling section side. The structure accommodates the power storage section and includes an impact absorption member arranged in a forward or rearward position on a side farther from a center position of the body section in the front-and-rear direction than the power storage section.

### Advantageous Effects of Invention

According to an aspect of the present disclosure, it is possible to prevent a power storage section from being damaged when an article conveyance device collides with, for example, an obstacle.

### BRIEF DESCRIPTION OF DRAWINGS

FIG. 1 is a perspective view illustrating an overall configuration of an article conveyance device in accordance with an embodiment of the present disclosure.

FIG. 2 is an exploded perspective view illustrating a configuration of a body section of the article conveyance device in accordance with the embodiment.

FIG. 3 is a perspective view illustrating configurations of a power storage section and a frame of the article conveyance device of the embodiment.

FIG. 4 is a perspective view illustrating a configuration around an impact absorption member of the article conveyance device in accordance with the embodiment.

FIG. 5 is a top view illustrating arrangement configurations of a first deformable part and a second deformable part of a first structure of the article conveyance device in accordance with the embodiment.

### DESCRIPTION OF EMBODIMENTS

### Embodiment

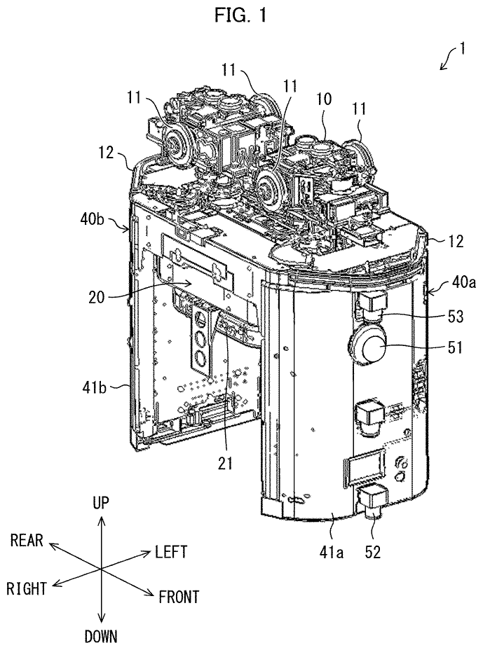

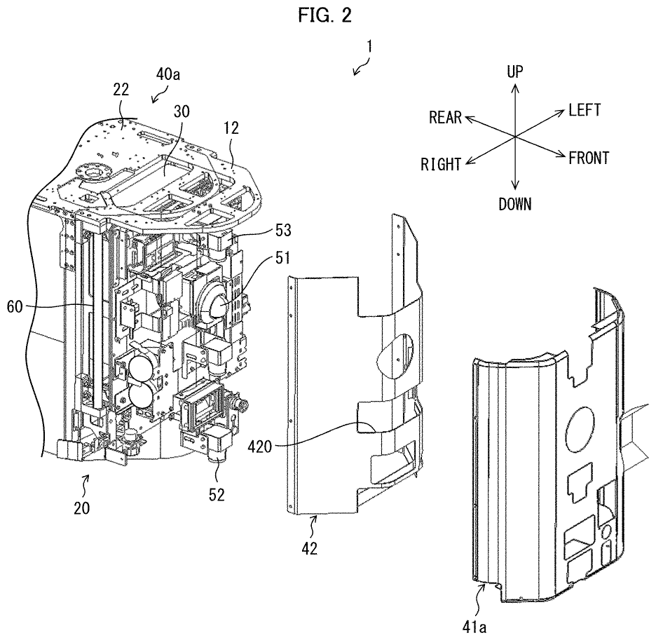

With reference to FIGS. 1 to 5, the following will describe an embodiment of present disclosure. FIG. 1 is a perspective view illustrating an overall configuration of an article conveyance device 1. FIG. 2 is an exploded perspective view illustrating a configuration of a body section 20 of the article conveyance device 1. Note that a travelling section 10 is omitted in FIG. 2. In the following description, an up-and-down direction, a front-and-rear direction, and a right-and-left direction of the article conveyance device 1 are defined as indicated by the arrows in FIG. 1 and FIG. 2.

### [Configuration of Article Conveyance Device]

As illustrated in FIG. 1 and FIG. 2, the article conveyance device 1 is, for example, a ceiling carrier configured to convey an article, such as a front opening unified pod (FOUP) accommodating a semiconductor substrate, along a travelling path (not illustrated) installed on or in the vicinity of the ceiling. Note that the article conveyance device 1 is not limited to a ceiling carrier and may be, for example, a carrier configured to convey an article along a travelling path installed on the floor surface.

The article conveyance device 1 includes a travelling section 10, a body section 20, and power storage sections 30. The travelling section 10 has two pairs of right and left travelling wheels 11. The travelling section 10 travels forward along a travelling path with use of the travelling wheels 11. A travelling direction of the travelling section 10 corresponds to a front-and-rear direction.

The travelling section 10 is arranged on a base frame 22. The base frame 22 is a plate-shaped member made of metal and constituting the upper surface of the body section 20. The base frame 22 is provided with bumpers 12 formed integrally at respective front and rear parts thereof. Note that the bumpers 12 include front and rear endmost parts of the article conveyance device 1.

The body section 20 is suspended from the travelling section 10. The body section 20 has a retention part 21 for retaining an object by hanging the object and a raising-and-lowering part (not illustrated) for raising and lowering the retention part 21. The retention part 21 retains an object with use of, for example, a holding claw. For example, the raising-and-lowering part includes a take-up belt, and raises and lowers the retention part 21 in an up-and-down direction by winding and unwinding the take-up belt. The article conveyance device 1 travels while keeping the retention part 21 raised, to convey the article.

At a front part of the body section 20, a first structure 40a is arranged. In addition, at a rear part of the body section 20, a second structure 40b is arranged. The first structure 40a and the second structure 40b each extend downward from a travelling section 10 side. The first structure 40a and the second structure 40b are each an example of a structure. Note that the body section 20 may have a structure only at one of the front part or the rear part of the body section 20.

### [Cover]

The first structure 40a has a first cover 41a. The second structure 40b has a second cover 41b. The first cover 41a and the second cover 41b are each an example of a cover.

The first cover 41a is made of, for example, a synthetic resin and is configured to cover the front face of the body section 20. The first cover 41a extends in an up-and-down direction. The first cover 41a has a shape such that both right and left end parts thereof are curved toward a center side of the body section 20 in a front-and-rear direction. The first cover 41a is fixed to a frame 60 (described later) of the first structure 40a with use of, for example, screws.

The second cover 41b is made of, for example, a synthetic resin and is configured to cover the rear face of the body section 20. The second cover 41b extends in an up-and-down direction. The second cover 41b has a shape such that both right and left end parts thereof are curved toward the center side of the body section 20 in a front-and-rear direction. The second cover 41b is fixed to a frame 60 of the second structure 40b with use of, for example, screws.

### [Impact Absorption Member]

Each of impact absorption members 42 is a member for absorbing impact that is applied to the corresponding power storage section 30 when the article conveyance device 1 that is travelling collides with, for example, an obstacle. The first structure 40a is provided with the impact absorption member 42 arranged between the first cover 41a and the power storage section 30. That is, the impact absorption member 42 of the first structure 40a is arranged in a forward position on a side farther from the center position of the body section 20 in the front-and-rear direction than the power storage section 30.

The impact absorption member 42 of the first structure 40a has a shape along an outer shape of the first cover 41a. That is, the impact absorption member 42 of the first structure 40a extends in an up-and-down direction. The impact absorption member 42 has a shape such that both right and left end parts thereof are curved toward a rear side.

The impact absorption member 42 of the first structure 40a is fixed to the frame 60 described later with use of, for example, screws. That is, the impact absorption member 42 of the first structure 40a is arranged between the first cover 41a and the frame 60.

The second structure 40b is also provided with the impact absorption member 42 arranged between the second cover 41b and the power storage section 30, although not illustrated. That is, the impact absorption member 42 of the second structure 40b is arranged on a rearward position on a side farther from the center position of the body section 20 in the front-and-rear direction than the power storage section 30.

The impact absorption member 42 of the second structure 40b also has a shape along an outer shape of the second cover 41b, although not illustrated. That is, the impact absorption member 42 of the second structure 40b extends in an up-and-down direction and has a shape such that both right and left end parts thereof are curved toward a front side.

The impact absorption member 42 of the second structure 40b is fixed to the frame 60 described later with use of, for example, screws. That is, the impact absorption member 42 of the second structure 40b is arranged between the second cover 41b and the frame 60.

The first structure 40a is provided with electronic devices such as a camera 51, an impact detection sensor 52, and an impact detection sensor 53. The camera 51 is a device for taking an image of, for example, another article conveyance device and an obstacle located in front of the camera 51. The impact detection sensor 52 is a sensor for detecting, for example, an obstacle. The impact detection sensor 53 is a sensor for detecting another article conveyance device located in front of the impact detection sensor 53. Note that the camera 51 may be omitted.

### [Power Storage Section]

As illustrated in FIG. 2, the first structure 40a accommodates the power storage section 30. The second structure 40b also has the power storage section 30, although not illustrated. The power storage sections 30, each made up from, for example, a battery, are members for storing excessive electricity in the article conveyance device 1.

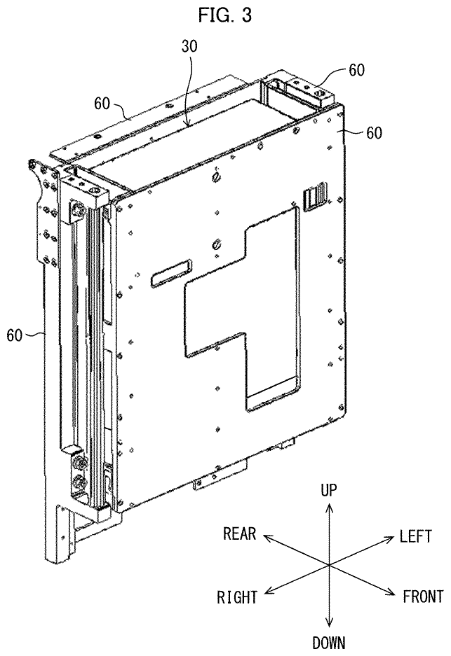

FIG. 3 is a perspective view illustrating the configurations of the power storage section 30 and the frame 60. As illustrated in FIG. 3, the power storage section 30 has a rectangular parallelepiped shape. The frame 60 is provided around the power storage section 30. The frame 60 is made up from, for example, a member made of metal. The frame 60 has, for example, plate-shaped members covering the front face and the rear face of the power storage section 30, plate-shaped members covering the left side face and the right side face of the power storage section 30, and support pillars extending in an up-and-down direction.

As described above, the first structure 40a has the frame 60 configured to surround the power storage section 30 thereof (see FIG. 2). The second structure 40b also has the frame 60 configured to surround the power storage section 30 thereof, although not illustrated. These frames 60 each have a function of reducing an impact that is applied to the corresponding power storage section 30 when the article conveyance device 1 collides with, for example, an obstacle.

An extinguishing sheet may be attached over the entire outer peripheral surface of each power storage section 30. For example, the extinguishing sheet is configured to generate aerosols containing extinguishing components, for example, when the power storage section 30 reaches a predetermined temperature or higher. This makes it possible to, when the power storage section 30 becomes hot and ignites, quickly extinguish the flames of the power storage section 30 in virtue of the extinguishing sheet.

### [Reinforcing Member]

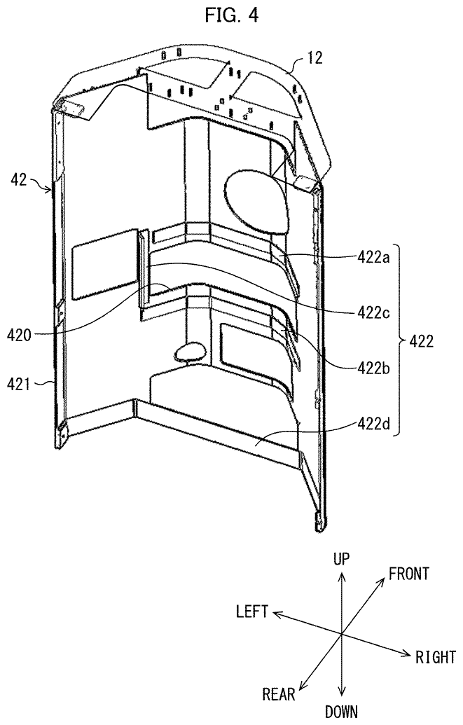

FIG. 4 is a perspective view illustrating a configuration around the impact absorption member 42. As illustrated in FIG. 4, the impact absorption member 42 includes a first member 421 and a second member 422 having a thickness greater than that of the first member 421. The second member 422 has a first reinforcing member 422a, a second reinforcing member 422b, a third reinforcing member 422c, and a fourth reinforcing member 422d. Note that in the example illustrated in FIG. 4, the impact absorption member 42 provided to the first structure 40a is illustrated.

The impact absorption member 42 is mainly constituted by the first member 421. The first member 421 extends in an up-and-down direction. The first member 421 has a shape such that both right and left end parts thereof are bent toward a center side in a front-and-rear direction. The material of the first member 421 is metal, such as aluminum or stainless steel. The first member 421 has, for example, an opening 420 having a rectangular shape.

The second member 422, which is an elongated plate-shaped member for reinforcing the first member 421, is made up from, for example, brackets or ribs. The material of the second member 422 is metal, such as stainless steel. Another possible material of the second member 422 may be, for example, a synthetic resin.

The first reinforcing member 422a, the second reinforcing member 422b, and the third reinforcing member 422c are attached to a surface around the opening 420 of the first member 421 on a power storage section 30 side with use of, for example, screws. The fourth reinforcing member 422d is attached to a surface of the lower end part of the first member 421 on the power storage section 30 side with use of, for example, screws.

Specifically, the first reinforcing member 422a is provided above the opening 420 and extends in a right-and-left direction. The first reinforcing member 422a abuts on the first member 421 and has a plurality of bent parts bent along an outer shape of the first member 421.

The second reinforcing member 422b and the first reinforcing member 422a are arranged side by side in an up-and-down direction. The second reinforcing member 422b is provided below the opening 420 and extends in a right-and-left direction. The second reinforcing member 422b abuts on the first member 421 and has a plurality of bent parts bent along an outer shape of the first member 421.

The member 422c is third reinforcing provided in the left of the opening 420 and extends in an up-and-down direction. The third reinforcing member 422c abuts on the first member 421. The length of the third reinforcing member 422c in an up-and-down direction is smaller than the length of the first reinforcing member 422a in a right-and-left direction and the length of the second reinforcing member 422b in a right-and-left direction. Note that the first reinforcing member 422a, the second reinforcing member 422b, and the third reinforcing member 422c are included in the first deformable part A1 described later.

The fourth reinforcing member 422d is provided on the lower end part of the first member 421 and extends in a right-and-left direction. The length of the fourth reinforcing member 422d in a right-and-left direction is greater than the length of the first reinforcing member 422a in a right-and-left direction and the length of the second reinforcing member 422b in a right-and-left direction. The fourth reinforcing member 422d has a plurality of bent parts bent along an outer shape of the first member 421. Note that the fourth reinforcing member 422d is included in the second deformable part A2 described later.

### [First Deformable Part and Second Deformable Part]

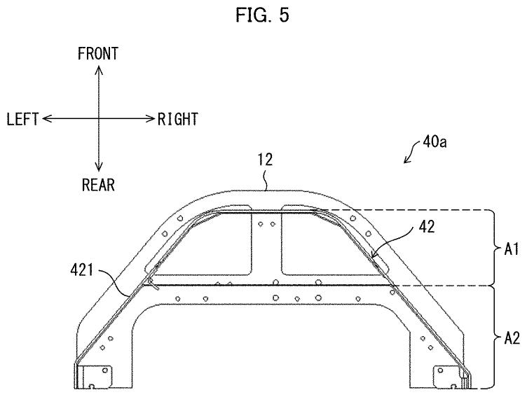

FIG. 5 is a top view illustrating arrangement configurations of the first deformable part A1 and the second deformable part A2 in the first structure 40a. Note that in FIG. 5, the bumper 12 and the impact absorption member 42 arranged below the bumper 12 are illustrated in a stacked state in an up-and-down direction, and a cross-sectional shape of the first member 421 viewed from above the impact absorption member 42 is illustrated.

As illustrated in FIG. 5, the impact absorption member 42 has the first deformable part A1 and the second deformable part A2. The first deformable part A1 is arranged so that a position of the first deformable part A1 includes a position farther from the center position of the body section 20 in a front-and-rear direction than the second deformable part A2.

That is, in the first structure 40a, the first deformable part A1 includes a front part of the first member 421 of the impact absorption member 42, the first reinforcing member 422a of the impact absorption member 42, the second reinforcing member 422b of the impact absorption member 42, and the third reinforcing member 422c of the impact absorption member 42. The second deformable part A2 includes the rear part of the first member 421 and the fourth reinforcing member 422d.

Note that the first reinforcing member 422a, the second reinforcing member 422b, and the third reinforcing member 422c are provided around the opening 420 of the first member 421. This makes it unlikely to deform part around the opening 420 by impact.

In the second structure 40b, although not illustrated, a first deformable part A1 thereof includes a rear part of the first member 421 of the impact absorption member 42, a first reinforcing member 422a of the impact absorption member 42, a second reinforcing member 422b of the impact absorption member 42, and a third reinforcing member 422c of the impact absorption member 42. A second deformable part A2 of the second deformable part A2 includes a front part of the first member 421 and a fourth reinforcing member 422d.

The first deformable part A1 of the impact absorption member 42 has a trapezoidal outer shape. The second deformable part A2 has a trapezoidal outer shape larger than that of the first deformable part A1. These first deformable part A1 and second deformable part A2 are arranged side by side in a front-and-rear direction. The bumpers 12 are arranged at the front and rear endmost parts of the article conveyance device 1.

In the article conveyance device 1 having such a configuration, the bumper 12 is first deformed when the article conveyance device 1 collides with, for example, an obstacle or another article conveyance device located in a front-and-rear direction of the article conveyance device 1. In a case where the impact is not absorbed by the bumper 12, the first cover 41a is deformed, and accordingly, the first deformable part A1 of the impact absorption member 42 is deformed. When the first deformable part A1 is deformed, the camera 51, the impact detection sensor 52, the impact detection sensor 53, and the like are damaged, but no damage is caused to the power storage section 30.

After the first deformable part A1 has been deformed, the second deformable part A2 is deformed. The second deformable part A2 is provided with the second reinforcing member 422b and thus likely absorbs an external impact.

When the second deformable part A2 is deformed, a power source, a driving part, and the like which are not illustrated are damaged, but no damage is caused to the power storage section 30. As described above, the first deformable part A1 and the second deformable part A2 absorb an external impact in a stepwise manner and accordingly, effectively reduce the impact applied to the power storage section 30 to prevent the power storage section 30 from being damaged.

### Effects of Embodiment

According to the article conveyance device 1 in accordance with the present embodiment described above, which is provided with the impact absorption member 42 in a forward position from the power storage section 30 in the first structure 40a, it is possible to reduce an impact that is applied to the power storage section 30 when the article conveyance device 1 collides with, for example, an obstacle located in front of the article conveyance device 1. In addition, the impact absorption member 42 is also provided in a rearward position from the power storage section 30 in the second structure 40b, and thus it is possible to reduce an impact that is applied to the power storage section 30 when the article conveyance device 1 collides with, for example, an obstacle located behind the article conveyance device 1. This makes it possible to prevent the power storage sections 30 and the article from being damaged.

In particular, the impact absorption members 42 are arranged between the first cover 41a and the power storage section 30 thereof and between the second cover 41b and the power storage section 30 thereof. Therefore, even if the first cover 41a and the second cover 41b are each deformed when the article conveyance device 1 collides with, for example, an obstacle, the impact absorption members 42 make it possible to reliably absorb the impacts applied to the power storage sections 30 from the first cover 41a and the second cover 41b.

Further, the power storage section 30 is surrounded by the frame 60 made of metal, as illustrated in FIG. 3. This makes it possible to reliably reduce an external impact applied to the power storage section 30 and thus makes it possible to more reliably prevent the power storage section 30 from being damaged.

Furthermore, each impact absorption member 42 has a configuration in which the second member 422 having a thickness greater than that of the first member 421 is attached to the first member 421, as illustrated in FIG. 4. The second member 422 thus makes it possible to improve a strength of the impact absorption member 42. This makes it possible to reliably reduce an impact that is applied to the power storage section 30 when the article conveyance device 1 collides with, for example, an obstacle.

### Other Embodiments

In the article conveyance device 1 in accordance with the embodiment described above, the first structure 40a is arranged at the front part of the body section 20, and the second structure 40b is arranged at the rear part of the body section 20, but this should not be construed as a limitation. For example, a configuration may be also possible in which the structure may be arranged only at one of the front part or the rear part of the body section 20.

In the article conveyance device 1 in accordance with the embodiment described above, the first structure 40a and the second structure 40b both accommodate the power storage sections 30, but this should not be construed as a limitation. Only one of the first structure 40a or the second structure 40b may accommodate the power storage section 30. In this case, the impact absorption member 42 only needs to be provided only to the structure in which the power storage section 30 is accommodated.

The article conveyance device 1 in accordance with the embodiment described above is provided with the first cover 41a arranged on the first structure 40a and the second cover 41b arranged on the second structure 40b, but this should not be construed as a limitation. For example, the cover may be arranged only on one of the first structure 40a or the second structure 40b, or no cover may be provided.

In the embodiment described above, the second member 422 is arranged on a surface on a power storage section 30 side in the first member 421, but this should not be construed as a limitation. The second member 422 may be arranged on a surface opposite to the power storage section 30 in the first member 421. The second member 422 only needs to be arranged in an area easily damaged in the first member 421, and the number of the second members 422 and an area in which the second member 422 is arranged can be changed as appropriate.

In the embodiment described above, the second member 422 is attached to the first member 421 with use of, for example, screws, but this should not be construed as a limitation. The second member 422 may be attached to the first member 421 with use of, for example, a double-sided tape. Alternatively, the second member 422 may be formed integrally with the first member 421.

In each of the first structure 40a and the second structure 40b, for example, heat sinks for releasing heat generated in the power storage section 30 may be arranged on an upper surface and both left and right side surfaces of the power storage section 30 inside the frame 60. According to this configuration, the heat generated in the power storage section 30 is favorably released through the heat sinks. This makes it possible to prevent the power storage section 30 from becoming hot.

In each of the first structure 40a and the second structure 40b, for example, a fan for blowing air to the power storage section 30 may be provided in a space above the power storage section 30. According to this configuration, the fan blows air to the power storage section 30, and thus it is possible to prevent the power storage section 30 from becoming hot.

Aspects of the present invention can also be expressed as follows:

An article conveyance device in accordance with Aspect 1 of the present disclosure includes: a travelling section configured to travel along a travelling path; a body section suspended from the travelling section; and a power storage section configured to store electricity. The body section includes a structure arranged at at least one of a front part or a rear part of the body section in a case where a travelling direction of the travelling section corresponds to a front-and-rear direction, the structure extending downward from a travelling section side. The structure accommodates the power storage section and includes an impact absorption member arranged in a forward or rearward position on a side farther from a center position of the body section in the front-and-rear direction than the power storage section.

According to the article conveyance device in accordance with Aspect 1 above, which is provided with an impact absorption member in a forward or rearward position from the power storage section, it is possible to reduce an impact that is applied to the power storage section when the article conveyance device collides with, for example, an obstacle. This makes it possible to prevent the power storage section from, for example, being damaged.

An article conveyance device in accordance with Aspect 2 of the present disclosure is configured, in Aspect 1, such that the structure further includes a cover configured to cover a front face or rear face of the body section. The impact absorption member is arranged between the cover and the power storage section.

According to the article conveyance device in accordance with Aspect 2 above, which is provided with the impact absorption member arranged between the cover and the power storage section, the impact absorption member makes it possible to reduce an impact applied to the power storage section, even if the cover is deformed when the article conveyance device collides with, for example, an obstacle. This makes it possible to effectively prevent the power storage section from, for example, being damaged.

An article conveyance device in accordance with Aspect 3 of the present disclosure is configured, in Aspect 2, such that the structure further includes a frame configured to surround the power storage section. The impact absorption member is arranged between the cover and the frame.

According to the article conveyance device in accordance with Aspect 3 above in which the power storage section is surrounded by the frame, it is possible to more reliably reduce an impact that is applied to the power storage section when the article conveyance device collides with, for example, an obstacle.

An article conveyance device in accordance with Aspect 4 of the present disclosure is configured, in any one of Aspects 1 to 3, such that the impact absorption member includes a first member and a second member having a thickness different from that of the first member.

According to the article conveyance device in accordance with Aspect 4 above in which the impact absorption member includes the first member and the second member having a thickness different from that of the first member, the second member makes it possible to improve a strength of the impact absorption member and to more reliably reduce an impact that is applied to the power storage section when the article conveyance device collides with, for example, an obstacle.

An article conveyance device in accordance with Aspect 5 of the present disclosure is configured, in any one of Aspects 1 to 4, such that the impact absorption member includes a first deformable part and a second deformable part. The first deformable part is arranged so that a position of the first deformable part includes a position farther from the center position of the body section in the front-and-rear direction than the second deformable part.

According to the article conveyance device in accordance with Aspect 5 above, the first deformable part and the second deformable part make it possible to effectively reduce an impact applied to the power storage section by, in a stepwise manner, absorbing the impact that is applied to the power storage section when the article conveyance device collides with, for example, an obstacle.

The present disclosure is not limited to the foregoing embodiments, but can be altered variously by a skilled person in the art within the scope of the claims, and the present disclosure also encompasses, in its technical scope, any configuration derived by appropriately combining technical means disclosed in the foregoing embodiments.

### REFERENCE SIGNS LIST

1 Article conveyance device
10 Travelling section
12 Bumper
20 Body section
30 Power storage section
40a First structure
40b Second structure
41a First cover
41b Second cover
42 Impact absorption member
60 Frame
421 First member
422 Second member
422a First reinforcing member
422b Second reinforcing member
422c Third reinforcing member
422d Fourth reinforcing member
A1 First deformable part
A2 Second deformable part

1. An article conveyance device comprising:
a travelling section configured to travel along a travelling path;
a body section suspended from the travelling section; and
a power storage section configured to store electricity,
the body section including a structure arranged at at least one of a front part or a rear part of the body section in a case where a travelling direction of the travelling section corresponds to a front-and-rear direction, the structure extending downward from a travelling section side,
the structure accommodating the power storage section and including an impact absorption member arranged in a forward or rearward position on a side farther from a center position of the body section in the front-and-rear direction than the power storage section.

2. The article conveyance device according to claim 1, wherein:
the structure further includes a cover configured to cover a front face or rear face of the body section; and
the impact absorption member is arranged between the cover and the power storage section.

3. The article conveyance device according to claim 2, wherein:
the structure further includes a frame configured to surround the power storage section; and
the impact absorption member is arranged between the cover and the frame.

4. The article conveyance device according to claim 1, wherein the impact absorption member includes a first member and a second member having a thickness different from that of the first member.

5. The article conveyance device according to claim 1, wherein:
the impact absorption member includes a first deformable part and a second deformable part; and
the first deformable part is arranged so that a position of the first deformable part includes a position farther from the center position of the body section in the front-and-rear direction than the second deformable part.
